(19) United States
(12) Patent Application Publication
(10) Pub. No.: US 2009/0002946 A1
(43) Pub. Date: Jan. 1, 2009

(54) Heat-dissipation module of light-emitting device

(75) Inventors: Alex Horng, Kaohsiung City (TW); Te-Chen Liu, Kaohsiung City (TW)

Correspondence Address: BACON & THOMAS, PLLC, 625 SLATERS LANE, FOURTH FLOOR, ALEXANDRIA, VA, 22314-1176, US

(73) Assignee: Sunonwealth Electric Machine Industry Co., Ltd., Kaohsiung City (TW)

(21) Appl. No.: 11/892,193

(22) Filed: Aug. 21, 2007

(30) Foreign Application Priority Data
Jun. 26, 2007 (TW) 096123000

(51) Int. Cl. H05K 7/20

(52) U.S. Cl. 361/697

(57) ABSTRACT

The present invention relates to a heat-dissipation module of a light-emitting device, which includes a cooling unit, at least a cooling fan and at least a light-emitting device. The light-emitting device is preferably an LED and is directly bonded to the cooling unit through a heat-conductor. The cooling unit and the heat conductor are constituted by a highly heat-conducting metal, e.g. aluminum, copper, gold and silver, or an alloy thereof, so as to absorb the heat of the light-emitting device by a heat-conducting means and achieve an ideal heat-dissipation performance by using the cooling fan to accelerating the air convection around the cooling unit.

### FIELD OF THE INVENTION

The present invention relates to a heat-dissipation module of a light-emitting device, and more particularly to one capable of providing excellent heat-dissipation performance, which breaks through the technological development bottleneck of LED and is not subjected to the poor heat-dissipation issue, so as to enhance the utility of the LED industry.

### BACKGROUND OF THE INVENTION

In view of the skyrocketing global energy cost and the continuously growing energy conservation concern, LED becomes an overnight rising star all of sudden. Given an example of LED street light, an application using 18 to 126 or so LED bulbs brings about a luminance in around 90 lumens/watt and an application using 70 to 80 or LED bulbs generates a luminance equivalent to that of a regular fluorescent lamp while the electricity consumption is only one quarter of the electricity consumed by a fluorescent lamp. Furthermore, if comparing with a conventional high voltage sodium street light, the consumed electricity could be saved about 50%; if the heat-dissipation problem can be handled well, the lifespan of the LED street light could last at least 50 thousands hours, which is roughly 14 years, without trading off the luminance.

Vendors in latest optoelectronic exhibition focus on the huge business opportunities of the display panels employing LED as the backlight source thereof one after the other. However, due to the issues of LED cost, light-emitting efficiency, heat-dissipation and so forth, the applications using LED as the backlight source of display panel hasn't been boomed yet.

At present, high-watt LEDs with 3 watts or more in the market can exactly solve the aforementioned issue of light-emitting efficiency. According to statistics, the revenue of the LED industry in Taiwan takes the share of 20% from the global revenue last year, which makes it the second largest LED supplying country in the world. As far as the upstream LED dice is concerned, the quantity of the blue and the AlGaInP quaternary high-luminance LED produced by Taiwan occupies 34% and 85% of the global share respectively, which rank number 1 globally. Based on the production quantity and technique, the LED cost shall be able to be gradually reduced. Whereas, the heat-dissipation issue of the LED having high watt in particular has remained as an unsolved problem.

### SUMMARY OF THE INVENTION

In view of the foregoing concern, the present invention thus provides a heat-dissipation module of a light-emitting device, which mainly targets at solving the heat-dissipation problem of LED lighting lamps, comprising:

a cooling unit constituted by a highly heat-conducting metal such as aluminum, copper, gold or silver or an alloy thereof and having a base board equipped with at least a cooling fin disposed on one side of the base board;

at least a cooling fan disposed on the side of the base board having the cooling fin disposed thereon to speed up the air convection surrounding the cooling fin by virtue of the cooling fan, so as to enhance the heat-dissipation efficiency of the base board; and

at least a light-emitting device, preferably a light-emitting diode, disposed on the other side of the base board of the cooling unit and directly bonded to the base board of the cooling unit through a heat conductor.

As the heat conductor is constituted by a highly heat-conducting metal, such as aluminum, copper, gold, silver, or an alloy thereof, heat of the light-emitting device can be absorbed by a heat-conducting means and directly conducted to the base board of the cooling unit through the heat conductor to achieve an optimal heat-dissipation performance by using the cooling fan to speed up the air convection around the cooling fin.

### BRIEF DESCRIPTION OF THE DRAWINGS

FIG. 1 is a three-dimensional schematic view showing a first preferred embodiment of the present invention;

FIG. 2 is a plane schematic view showing the first preferred embodiment of the present invention;

FIG. 3 is a three-dimensional schematic view showing a second preferred embodiment of the present invention;

FIG. 4 is a plane schematic view showing the second preferred embodiment of the present invention;

FIG. 5 is a three-dimensional schematic view showing a third preferred embodiment of the present invention;

FIG. 6 is a plane schematic view showing the third preferred embodiment of the present invention;

FIG. 7 is a three-dimensional schematic view showing a fourth preferred embodiment of the present invention; and

FIG. 8 is a three-dimensional schematic view showing a fifth preferred embodiment of the present invention.

### DETAILED DESCRIPTION OF THE PREFERRED EMBODIMENT

To make the object, characteristic and functions more self-explanatory and comprehensive, several preferred embodiments are provided as follows together with illustrative figures for detailed description.

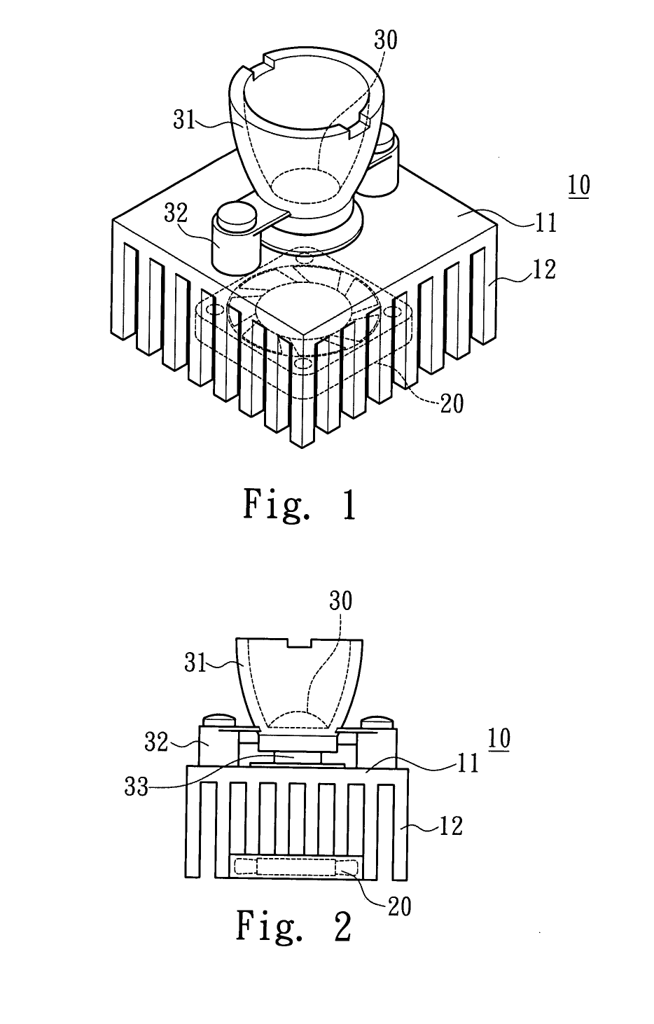

Please refer to FIG. 1 and FIG. 2 for the illustration of the first preferred embodiment. The heat-dissipation module of a light-emitting device includes:

a cooling unit 10 having a base board 11 constituted by a highly conductive metal, e.g. aluminum, copper, gold or silver, or an alloy thereof, in which one side of the base board 11 has at least one cooling fin 12 taking the form of a plate or a column;

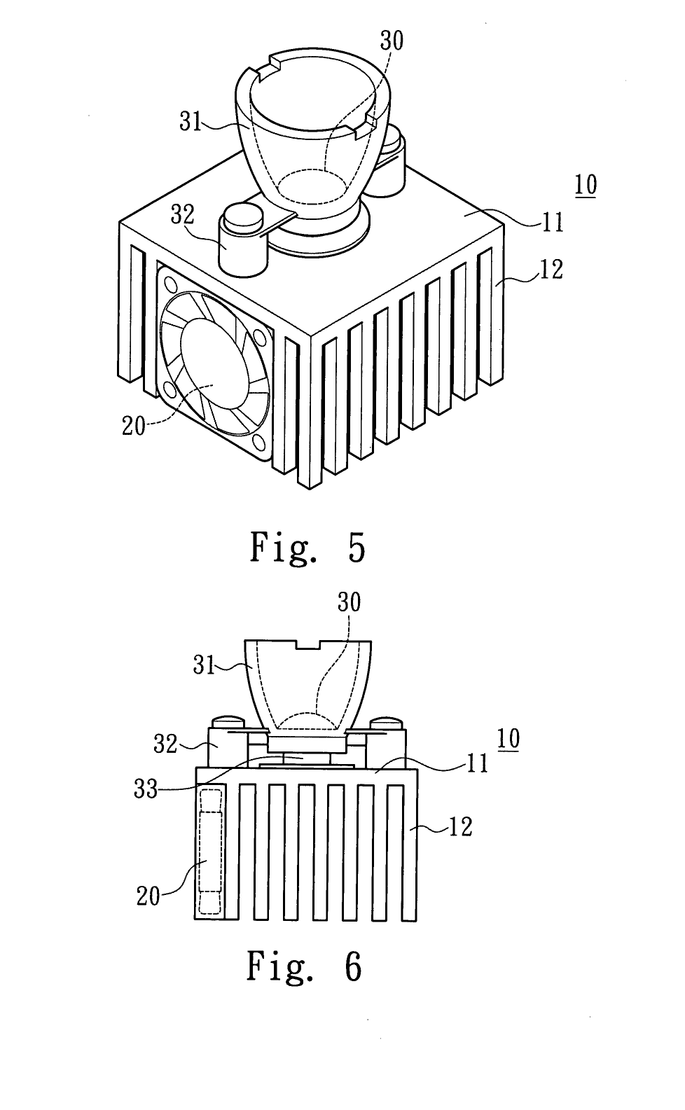

at least a cooling fan 20 located on the side of the base board 11 having the cooling fin 12 thereon, in which the cooling fan 20 could be chosen from one of an axial flow fan and a blower and aligned horizontally (as shown in FIG. 1 and FIG. 2) or vertically (as shown in FIG. 5 and FIG. 6) to the base board 11 of the cooling unit 10 so as to speed up the air convection around the cooling fin 12 with the cooling fan 20 and further increase the heat-dissipation efficiency of the base board 11;

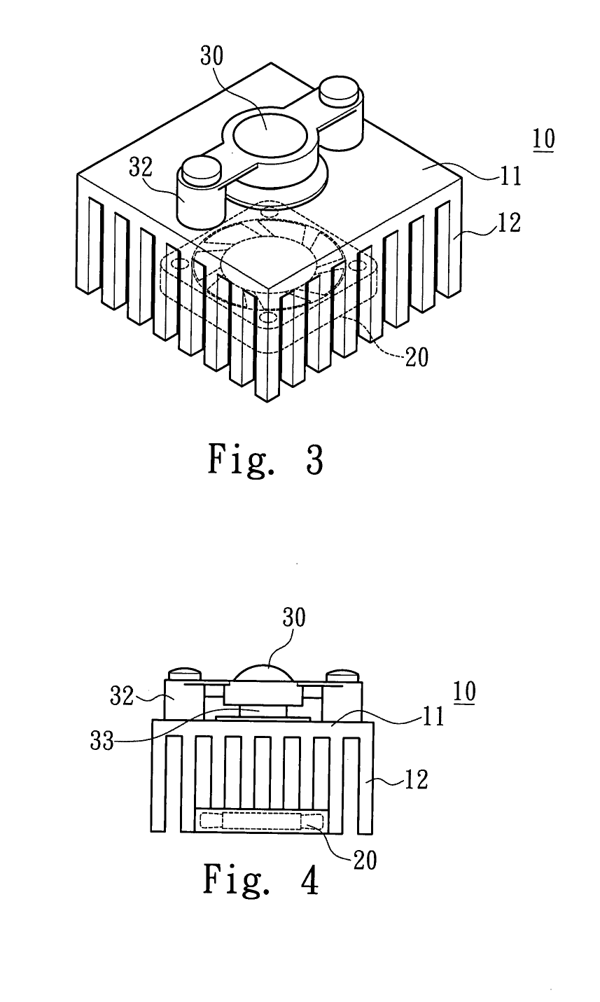

at least a light-emitting device 30, preferably a LED, additionally provided with a lamp shade 31 (as shown in FIG. 1 and FIG. 2) on a periphery thereof based on actual requirement or directly exposed to external environment (as shown in FIG. 3 and FIG. 4), in which the light-emitting device 30 is located on the side of the base board 11 of the cooling unit 10 having no cooling fin 12 disposed thereon and is disposed on a base 32, the bottom of the base 32 has a heat-conducting portion 33 whose one end is connected with the light-emitting device 30 and the other side is directly bonded to the base board 11 of the cooling unit 10. The material of heat-conducting portion 33 is selected from a metal with highly heat-conducting capability, e.g. aluminum, copper, gold or silver, or an alloy thereof, so that the heat-conducting portion 33 can absorb the heat of the light-emitting device 30 by a heat conduction means and the heat is directly conducted to the base board 11 of the cooling unit 10 through the highly heat-conducting capability of the heat-conducting portion 33.

In addition, when the heat-conducting portion 33 is directly attached to the base board 11 of the cooling unit 10, a contact surface therebetween can be coated with a thermal compound to enhance the heat-conducting efficiency of the heat-dissipation module.

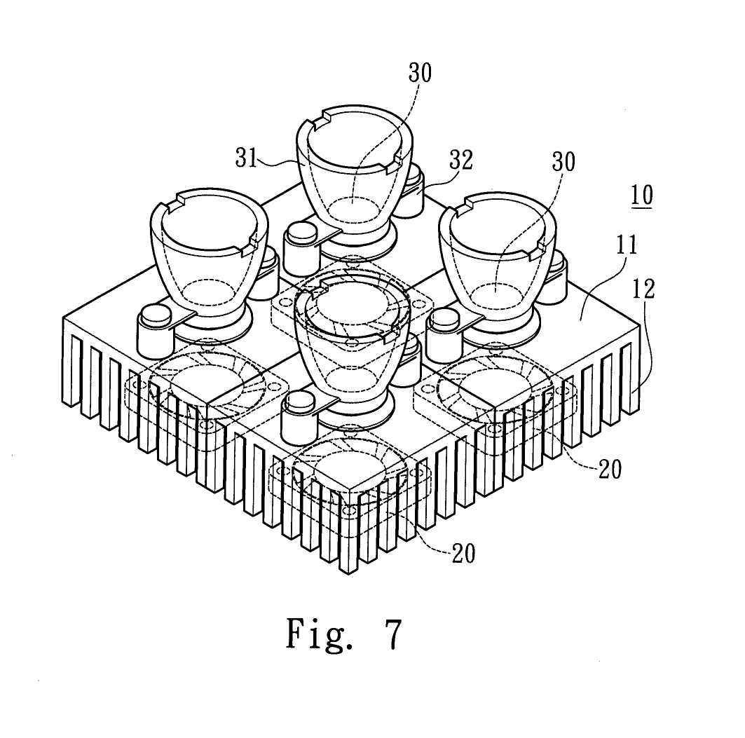

When lighting of large area is required, the heat-dissipation module of the light-emitting device 30 in the present invention can be combined and aligned for operation. The heat-dissipation modules of two or more light-emitting devices are aligned in form of a horizontal bar, or the heat-dissipation modules of four or more light-emitting devices, as shown in FIG. 7, are aligned in form of a matrix.

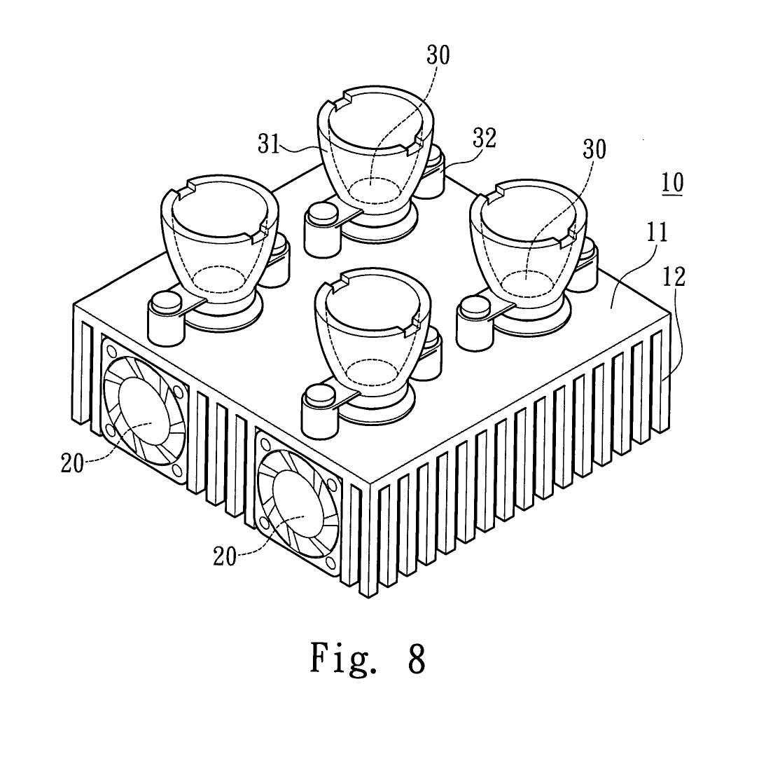

Please further refer to FIG. 8. The present invention can also have at least two light-emitting devices 30 (an arrangement of four light-emitting devices shown in FIG. 8) disposed on the base board 11 of the cooling unit 10 and arranged in form of a horizontal bar or a matrix. At least one cooling fan 20 (an arrangement of two cooling fans shown in FIG. 8) is incorporated to assist the cooling fin 12 for accelerating heat dissipation and enhancing the heat-dissipation efficiency of the base board 11.

In sum, the light-emitting device 30 of the present invention is directly bonded to the base board 11 of the cooling unit 10 through the heat-conducting portion 33 to effectively raise the heat-dissipation efficiency of the light-emitting device; from the above-mentioned characteristics those features not only have a novelty among similar products and a progressiveness but also have an industry utility.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A head-dissipation module of a light-emitting device, comprising:
a cooling unit having a base board equipped with at least a cooling fin;
at least a cooling fan disposed on one side of said base board of said cooling unit having said at least a cooling fin; and
at least a light-emitting device disposed on the other side of said base board of said cooling unit having a heat conductor whose one end is connected with said light-emitting device and the other end is connected with said base board of said cooling unit.

2. The heat-dissipation module of claim 1, wherein said cooling unit is constituted by a highly heat-conductive metal selected from a group consisting of aluminum, copper, gold and silver.

3. The heat-dissipation module of claim 1, wherein said cooling unit is constituted by a highly heat-conductive alloy selected from a group consisting of alloys of aluminum, copper, gold and silver.

4. The heat-dissipation module of claim 1, wherein said cooling fin of said cooling unit takes a form selected from a group consisting of a plate and a column.

5. The heat-dissipation module of claim 1, wherein said cooling fan is selected from a group consisting of an axial flow fan and a blower.

6. The heat-dissipation module of claim 1, wherein said cooling fan is disposed in a direction parallel with said base board of said cooling unit.

7. The heat-dissipation module of claim 1, wherein said cooling fan is disposed in a direction perpendicular to said base board of said cooling unit.

8. The heat-dissipation module of claim 1, wherein said light-emitting device is a light-emitting diode.

9. The heat-dissipation module of claim 1, wherein said heat conductor is constituted by a highly heat-conductive metal selected from a group consisting of aluminum, copper, gold and silver.

10. The heat-dissipation module of claim 1, wherein said heat conductor is constituted by a highly heat-conductive alloy selected from a group consisting of alloys of aluminum, copper, gold and silver.

11. The heat-dissipation module of claim 1, wherein said light-emitting device is fixed on said base board of said heat conductor through a base.

12. The heat-dissipation module of claim 1, wherein a contact surface between said heat conductor and said base board of said cooling unit is coated with a thermal compound.

13. The heat-dissipation module of claim 1, wherein said light-emitting device has a lamp shade disposed on a periphery thereof.

14. The heat-dissipation module of claim 1, wherein said base board of said cooling unit has at least two light-emitting devices thereon and said light-emitting devices are aligned in form of a horizontal bar.

15. The heat-dissipation module of claim 1, wherein said base board of said cooling unit has at least four light-emitting devices disposed thereon and said light-emitting devices are aligned in form of a matrix.

16. The heat-dissipation module of claim 1 is aligned in form of a matrix.
